(19) United States
(12) Patent Application Publication
(10) Pub. No.: US 2008/0137878 A1
(43) Pub. Date: Jun. 12, 2008

(54) Electronic method for reducing noise in the ear canal using feed forward techniques

(76) Inventors: Mead C. Killion, Elk Grove Village, IL (US); Peter L. Madaffari, Camden, ME (US)

Correspondence Address: MCANDREWS HELD & MALLOY, LTD, 500 WEST MADISON STREET, SUITE 3400, CHICAGO, IL, 60661, US

(21) Appl. No.: 11/637,532

(22) Filed: Dec. 12, 2006

(51) Int. Cl. H03B 29/00

(52) U.S. Cl. 381/71.6

(57) ABSTRACT

A feed forward technique is used to provide active noise reduction within an ear canal blocked with a passive noise reducing apparatus such as an earplug. Sound outside the ear is monitored and converted into an electronic signal that is opposite in phase from the anticipated sound leakage in the ear canal. The electronic signal is converted back into sound and fed forward into the ear to provide a cancellation effect with the actual sound leakage.

### CROSS-REFERENCE TO RELATED APPLICATIONS

This application makes reference to, and claims priority to, U.S. provisional application Ser. No. 60/748,869 filed Dec. 12, 2005.

### FIELD OF THE INVENTION

Certain embodiments of this invention relate to methods for reducing the noise within an ear canal during use of earphones and earplugs. More specifically, certain embodiments of the invention relate to active noise reduction techniques used in conjunction with passive noise reduction techniques to attenuate sound within an ear canal during use of earphones and earplugs.

### BACKGROUND OF THE INVENTION

Insert earphones with built in receivers are used to both limit the intrusion of unwanted sound into the ear canal and to produce wanted sound from an electronic device such as a music player or a communication device. By inserting directly into the ear canal, insert earphones not only provide a higher quality direct sound feed into the ear, they are also able to serve a passive noise reduction technique by obstructing the migration of external sound into the ear.

An example of a device providing passive noise attenuation is the ER-4 earphone of Etymotic Research Inc. The ER-4 is generally the subject of U.S. Pat. No. 5,887,070, and was developed for hi-fidelity music applications. U.S. Pat. No. 5,877,070 is incorporated by reference herein in its entirety. Another example is the ER-6 earphone, also of Etymotic Research. Both the ER-4 and the ER-6 are insert earphones that effectively provide passive noise attenuation within the ear.

Unfortunately, passive noise reduction alone will often allow an annoying degree of unwanted external noise to enter the ear canal. Sound may leak around a seal that is improperly installed into the ear or where an insert earphone is poorly designed for the shape of a particular user's ear canal. Even a well designed and properly installed insert earphone, however, will still inevitably allow a degree of sound to migrate from the external field into the ear in loud environments.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method for reducing noise in connection with insert earphones and earplugs, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF THE DRAWINGS

FIG. 1 illustrates an insert earphone assembly;

FIG. 2 is a cross-sectional view of one embodiment of an earphone of FIG. 1;

FIG. 3 shows a piece of resilient material used in conjunction of the earphone of FIG. 1;

FIG. 4 is a cross-sectional view taken substantially along line 4-4 of FIG. 2;

FIG. 5 depicts a model of an electrical feed forward active noise reduction circuit;

FIG. 6 depicts another embodiment of a model of an electrical feed forward active noise reduction circuit that includes an external audio output;

FIG. 7 depicts another embodiment of a model of an electrical feed forward active noise reduction circuit;

FIG. 8 depicts earphone of FIG. 2 with a microphone installed;

FIG. 9 is a graphical representation of a SPICE® calculation of the noise attenuation of the feed forward technique when applied to an ideal receiver;

FIG. 10 is a SPICE® calculation of the noise attenuation of the feed forward technique when applied to an ideal receiver when damping is applied to the receiver;

FIG. 11 is a graphical representation of a SPICE® calculation of the noise attenuation of the feed forward technique when applied to receiver commonly used in hearing aids;

FIG. 12 is a graphical representation of a SPICE® calculation of the noise attenuation of the feed forward technique when applied to a commercial earphone receiver;

FIG. 13 is a graphical representation of experimental results of the noise attenuation in a simulated ear canal using the passive noise reduction and feed forward active noise reduction technique; and

FIG. 14 depicts another embodiment of a model of an electrical feed forward active noise reduction circuit that was used in the experiment to obtain the results from FIG. 10.

### DESCRIPTION OF A PREFERRED EMBODIMENT

Introduction

Aspects of the present invention provide an electrical solution to the mechanical problems involved with passive noise attenuation provided by existing earplugs and insert earphones using a feed forward technique that develops a cancellation scheme for sound developed in an ear canal blocked by earplugs or a passive noise reducing insert earphone. In a preferred embodiment, an earphone assembly is used comprising at least one earphone providing passive noise reduction, a feed forward circuit for attenuating sound within the ear, and cables for connecting to an external audio device

Ear Phone Assembly

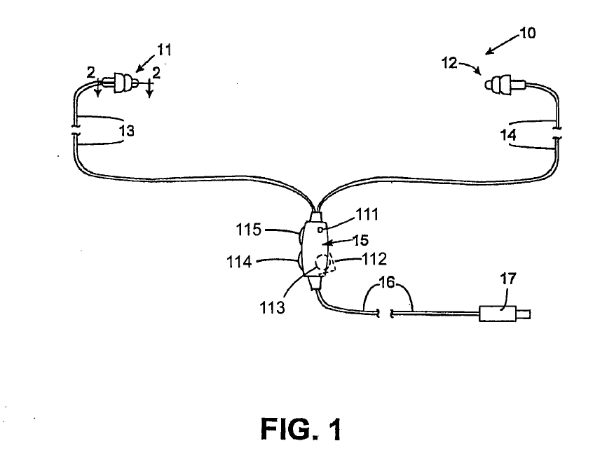

In FIG. 1, reference numeral 10 generally designates an earphone assembly which is constructed in accordance with the principles of this invention and which is suitable for use by an audiophile, for example. It will be understood, however, that a number of features of the invention are not limited to any particular use. Certain features may be used, for example, in the construction of two-way voice communication devices having external acoustic noise reduction as described by U.S. patent application No. 20040165720, which application is incorporated herein by reference in its entirety.

The illustrated assembly 10 includes a pair of earphones 11 and 12 for insertion into the entrances of the ear canals of a user. A pair of cables 13 and 14 connect earphones 11 and 12 to a junction unit 15 and a common cable 16 connects the junction unit 15 to a plug connector 17 which may be connected to an output jack of a external audio device (not shown) such as stereophonic amplifier, for example. In one embodiment, the junction unit 15 may comprise a battery warning light 111 to serve as an indication when a battery 113 stored within the junction unit 15 behind a battery door 112 needs replacement. A phase adjuster 115 and an amplitude adjuster 114 may also be located on the junction unit 15 to control the settings of the feed forward circuitry, discussed infra, which may be located in the junction unit 15 in one embodiment. In another embodiment, an additional phase adjuster and amplitude adjuster would be provided to allow for adjustment of the feed forward circuits as applied to each earphone 11 and 12 individually.

Passive Noise Reduction

It is intended for the feed forward circuitry to work with any insert earphones that provide passive noise reduction by forming a seal within the ear canal. Insert earphones such as described by U.S. Pat. No. 5,887,070 issued to Iseberg, et. al, and U.S. Pat. No. 6,993,144 issued to Wilson, et al. accurately depicts an example of an earplug that provides passive noise reduction by blocking sound external to the ear from entering the ear canal, while delivering wanted sound from an audio device. Both of these patents are incorporated herein by reference in their entirety.

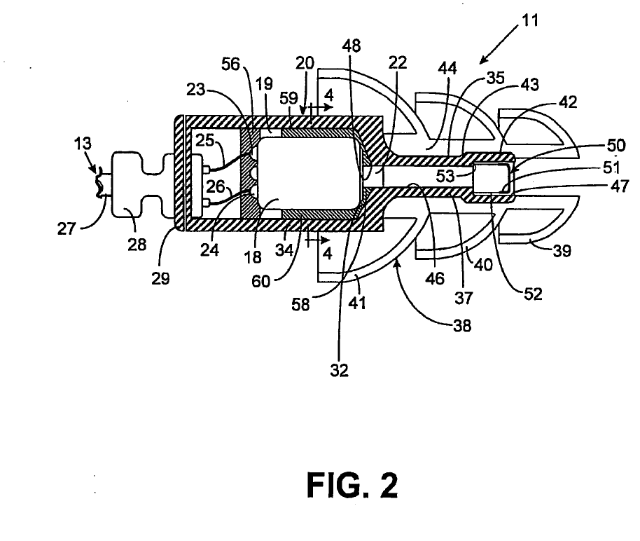

An example of an embodiment of such an insert earphone is depicted in FIGS. 2-4. Passive noise reduction techniques are solved by the mechanical makeup of the earplug apparatus 10 itself. FIG. 2 is a cross-sectional view of the earphone 11, the construction of the other earphone 12 being preferably identical to that of the earphone 11. The earphone 11 comprises a receiver 18 which is mounted in a chamber portion 19 of a housing member 20. The receiver 18 has an acoustic output port and has electrical input terminals 23 and 24 and is operative for generating an acoustic output signal at the output port 22 as a function of an electrical signal applied to the positive receiver terminal 23 and negative receiver terminal 24. The terminals 23 and 24 are connected through wires 25 and 26 to conductors of the cable 13 and an outer sheath 27 of the cable 13 is bonded to a strain relief member 28. Member 28 is secured in an opening of an end cap 29 which is secured to one end of the housing member 20 to close one end of the chamber portion 19.

The housing member 20 includes a wall 32 at an opposite end of the chamber portion 19 and an outer wall 34 of the chamber portion 19 which is in surrounding relation to the receiver 18 and which may preferably be of generally cylindrical form.

The housing member 20 further includes a tubular portion 35 which projects from the end wall 32 of the chamber portion of the housing member and which is inserted in an opening 37 of an acoustic coupling device 38 arranged to be inserted into the entrance of an ear canal of a user. As shown, the coupling device 38 is in the form of an eartip of a soft compliant material and has three outwardly projecting flange portions 39, 40 and 41 which are of generally conical form and of progressively increasing diameters, arranged to conform to the inner surface portions of the entrance of the ear canal of the user and to provide a seal limiting transmission of sound to the ear canal.

An end section 42 of the tubular portion 35 is of increased cross-sectional size to provide an external shoulder 43 in facing relation to the wall 32. In assembly, a portion 44 of the compliant material of the device 38 is stretched over the end section 42 and then expands into the space between the shoulder 43 and the wall 32 as shown, so as to lock the device 38 and housing member 20 together while permitting disassembly when desired.

Custom earmolds or other types of coupling devices may be substituted for the illustrated device 38, the subassembly of the housing member 20, receiver 18 and other parts being thus usable with various types of coupling devices.

In accordance with further important features of the invention, the tubular portion 35 defines a passage 46 which has an outlet end portion 47 for propagation of acoustic energy into the ear canal of a user and an inlet end portion 48 in communication with the outlet port 22 [20] of the receiver 18. The outlet port 22 is preferably in the form of a tubular member which is fitted into the inlet end portion 47 of the passage 46 as shown. An acoustic damper 50 is fitted in the outlet end portion 47 of the passage 46 and, as illustrated, includes a cup-shaped screen member 51 secured in a cylindrical support member 52. The outlet end portion 47 preferably has an enlarged diameter to provide a shoulder 53 operative to limit movement of the damper 50 toward the receiver 18 during assembly and to accurately fix its position. As shown, the portion of the screen member 51 which is transverse to the direction of sound transmission is in recessed relation to the end of the tubular housing portion 35 [22] and the terminal end of the tubular housing portion is spaced a substantial distance from the terminal end of the coupling device, the result being that problems with wax accumulations on the screen are minimized. However, should such accumulations occur, a special removal tool as hereinafter described may be used to remove a clogged damper 50 which can then be replaced with a new damper.

With the construction as thus far described, the housing member 20 can be readily molded from plastic in one piece and it serves the functions of connecting to the outlet port of the receiver, supporting the damper, providing a sound passage and releasably connecting to a coupling device which may be of various possible types, such functions being performed with a high degree of accuracy and reliability.

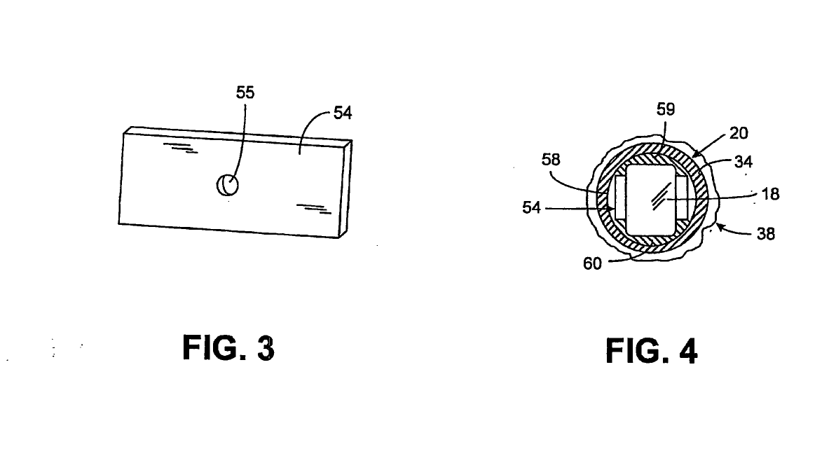

Additional important features relate to the provision of a resilient support for the receiver 18 to minimize problems with noise and vibrations while facilitating assembly of the earphone. A piece of foam material 54 is provided having a generally rectangular form and a central opening 55 as depicted in FIG. 3. In assembly, strain relief member 28 at the end of the cable 13 is installed in an opening in the end cap 29 and the conductors of the cable are connected directly or through the separate wires 25 and 26 as illustrated to the terminals 23 and 24 of the receiver 18, being optionally extended through a resilient foam element 56, as shown. Then the output port 22 of the receiver is inserted in the opening 55 of the piece 54 and the receiver is inserted into the chamber portion 19 and moved toward the wall 32 to press fit the output port 22 into the inlet end portion 48 of the passage 46. During this assembly step, a portion 58 of the piece 54 is compressed between the end of the receiver 18 and the wall 32 and portions 59 and 60 of the piece 54 are folded back and compressed between the receiver and the outer wall 34 of the chamber portion 19. As shown in the cross-sectional view of FIG. 4, parts of the folded-back portions 59 and 60 extend along the sides of the receiver 18 as well as along the top and bottom of the receiver 18. This assembly step is readily and quickly performed and results in a resilient support of the receiver 18 within the housing member 20 in a manner such as to minimize transmission of noise and vibrations thereto, functioning with a high degree of reliability. It also results in an acoustic seal between the output port 22 and the inlet end 48 of passage 46. As a final assembly step, an epoxy or equivalent bonding means is used to secure the end cap 29 to the end of the housing member 20.

It should be noted that while the above describes a passive noise reduction technique that may be used in connection with a feed forward active noise reduction technique, this invention is by no means limited to such embodiment. It is contemplated that the feed forward active noise reduction technique may be used with any form of passive noise reduction.

The Feed Forward Technique

A conventional sub-miniature microphone 67 generally has a signal out terminal and a ground terminal. For the purpose of this application, the signal out terminal will be defined as the positive terminal if a positive sound pressure entering the microphone produces a more positive electrical signal at the signal out terminal than at the ground terminal. Similarly conventional sub-miniature receivers (speakers) have two or more terminals. When used in two terminal applications, the positive terminal will be defined as that terminal which, when fed a signal more positive than present at the opposing terminal, produces a positive output sound pressure level. Additionally, for purposes of this application, it is contemplated that either a two-terminal potentiometer, a three-terminal resistor with an adjustable center connection (often referred to as a “pot”), or a rheostat may be interchanged with any potentiometer described in this application.

The feed forward technique can be used to cancel an acoustical signal in a blocked ear canal that originated outside the ear. An electrical circuit 100 may be located internal to or external to the housing 20 of the insert earphone 11. The electrical circuit 100 feeds forward a signal converted from sound outside the ear into the ear canal may be used in conjunction with an insert earphone 11 providing passive noise reduction, such as described above, but in no way is limited to such an embodiment. Examples of insert earphones that may also be used in conjunction with the feed forward technique are Insert earphones such as described by U.S. Pat. No. 5,887,070 issued to Iseberg, et. al, and U.S. Pat. No. 6,993,144 issued to Wilson, et al. Further, the technique may also be used in other audio devices inserted into the ear, for example, in a two-way voice communication devices having external acoustic noise reduction as described by U.S. patent application No. 20040165720.

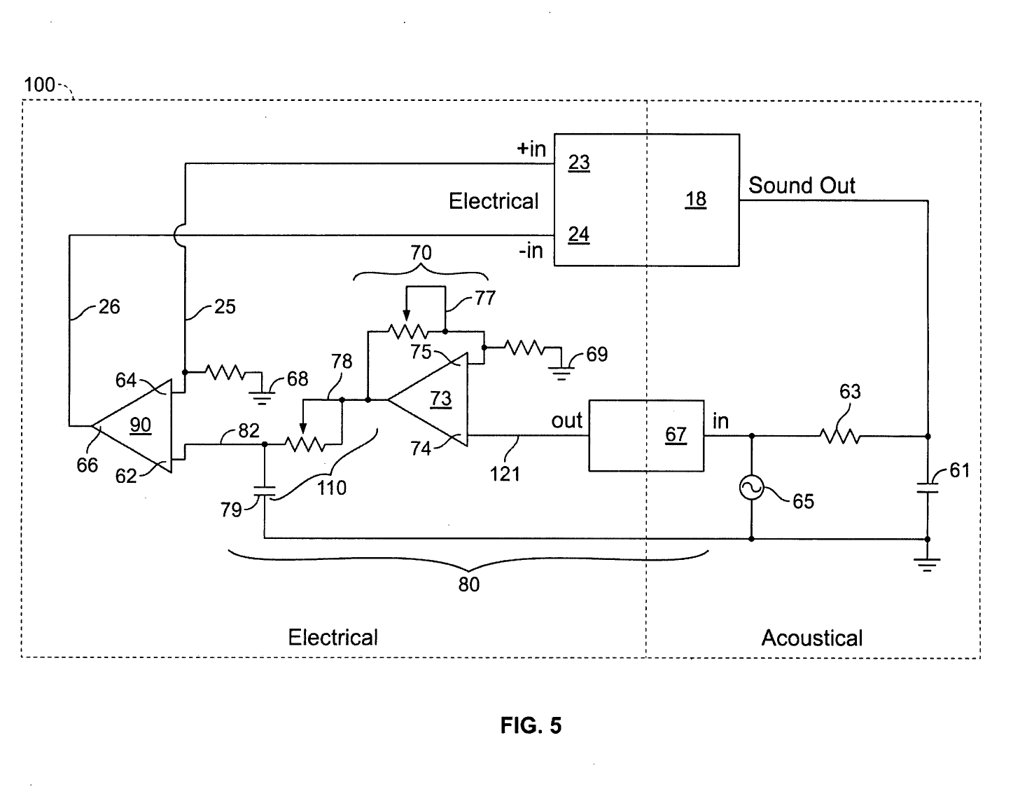

Various embodiments of the feed forward circuit are depicted by FIGS. 5-7, and FIG. 12. The right side of FIG. 5 models the acoustical aspect of the technique. The ear canal of an earplug wearer is modeled in the figure as a capacitor 61. The sound path that bypasses the earplug and enters the ear canal is modeled as a resistor 63. The sound external to the ear is modeled as a voltage source 65.

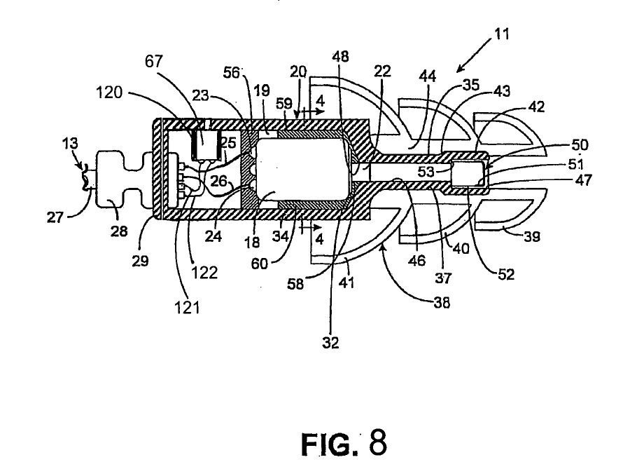

The left side of FIG. 5 represents the electronic circuitry of an embodiment of the feed forward technique. A microphone 67 converts sound external to the ear into a voltage. In one embodiment, the microphone 67 may be located within the end cap 29 of the insert earphone 11, facing outward. FIG. 8 depicts another embodiment where the microphone may be located within a the earphone 11, attached to the earphone housing 20 via a microphone housing 120. In this embodiment, microphone wires 121 and 122 connect the microphone 67 to the cable 13, which electrically connects the microphone 67 to the feed forward circuit 100. A high gain amplifier 73 comprises a positive signal input terminal 74, a negative input terminal 75, and an output terminal 76. The positive input terminal 74 is connected to the microphone 67 via a wire 25. The negative input terminal 75 is connected to an adjustable amplitude adjusting potentiometer 77, which also connects to the output terminal 76 of the high gain amplifier 73. Together, the high gain amplifier 73 and the amplitude adjusting potentiometer 77 create a loop that serves as a signal amplitude adjuster loop 70. The signal amplitude adjuster loop 70 may also contain a ground source 69. The signal amplitude adjuster loop 70 provides a means for the circuit 100 to account for certain variables in the system such as the properties of different types of microphones 67, or receivers 18.

Connected to the output terminal 76 of the high gain amplifier 73 is a phase shifter, 110 comprised of a phase shifting potentiometer 78 and a phase shifting capacitor 79. Together the microphone 67, the signal amplitude adjuster loop 70, and the phase shifter 110 comprise the acoustical to electrical voltage converter stage 80. The phase shifting potentiometer 78 and the phase shifting capacitor 79 are modeled to mimic the sound leakage path of external sound 65 into the ear canal. The impedance of the phase shifting potentiometer 78 or of the capacitor 79 may be adjustable, for example, by manipulation of a phase adjuster 115, to compensate for the phase of the sound leakage into the ear canal. In one embodiment, the phase shifter 110 also performs a frequency controlled level shift that tracks the relative amplitude of the sound leakage into the ear canal.

A voltage to current source converter (“VCSC”) 90 converts the voltage delivered by the sound to voltage converter 80 into a current signal, and shifts the signal 180 degrees. In one embodiment, the VCSC 90, may be a general purpose operational amplifier. The VCSC 90 has a positive signal input terminal 62 that is connected in series with the acoustical to electrical voltage converter stage 80 via a wire 82 and the phase shifting capacitor 79. A negative input terminal 64 of the VCSC 90 is electrically connected to the receiver 18 via a wire 25 and may have a ground source 68. The output terminal 66 of the VCSC 90 is also electrically connected to the receiver 18 via a wire 26.

Multiple means exist to create the desired signal change of 180 degrees. In one embodiment, the output terminal 66 of the VCSC 90 is connected via wire 26 to the negative input terminal 24 of the receiver 18, and the negative input terminal 64 of the VCSC 90 is connected to the positive input terminal 23 of the receiver 18 via wire 25.

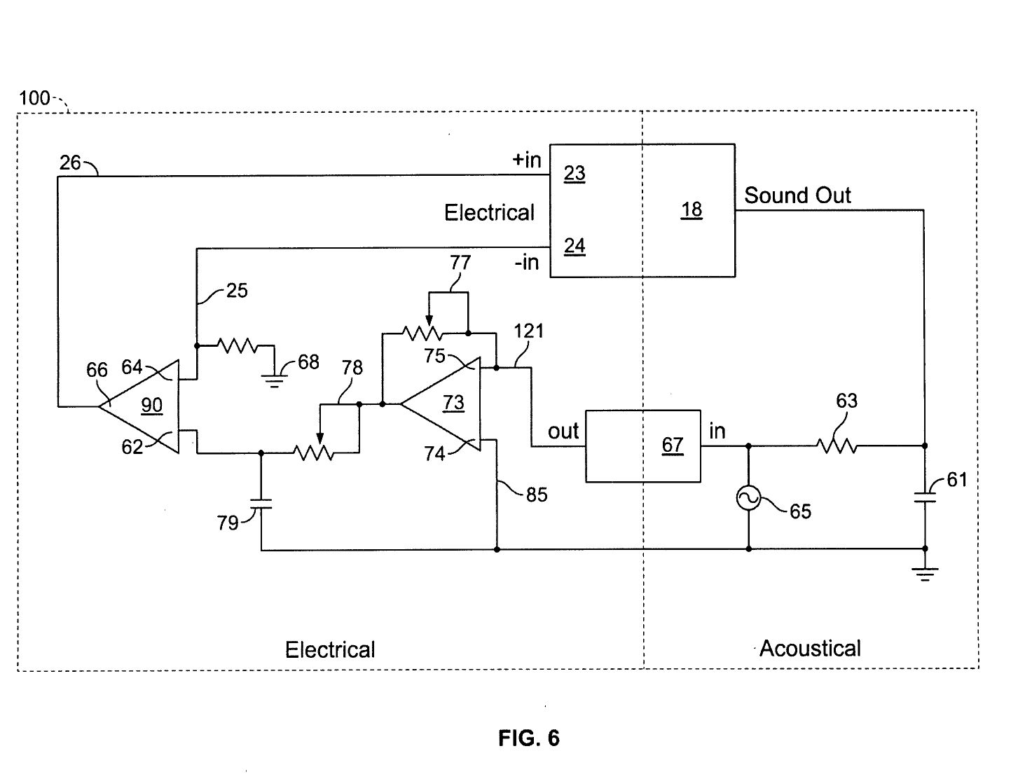

In another embodiment of the feed forward circuit 100, as depicted in FIG. 6, the high gain amplifier 73 is used to invert the signal 180 degrees. In this embodiment, the output impedance of the microphone 67 is connected to the negative terminal 75 of the high gain amplifier 73 and acts to set the gain of that stage. The positive terminal 74 is fed back to connect with the phase shifting capacitor 79. In this embodiment, the output terminal 66 of the VCSC 90 connects directly with the positive input terminal 23 of the receiver 18 via wire 26. Accordingly, the negative input terminal 64 of the VCSC 90 connects directly with the negative input terminal 24 of the receiver 18 via a wire 25

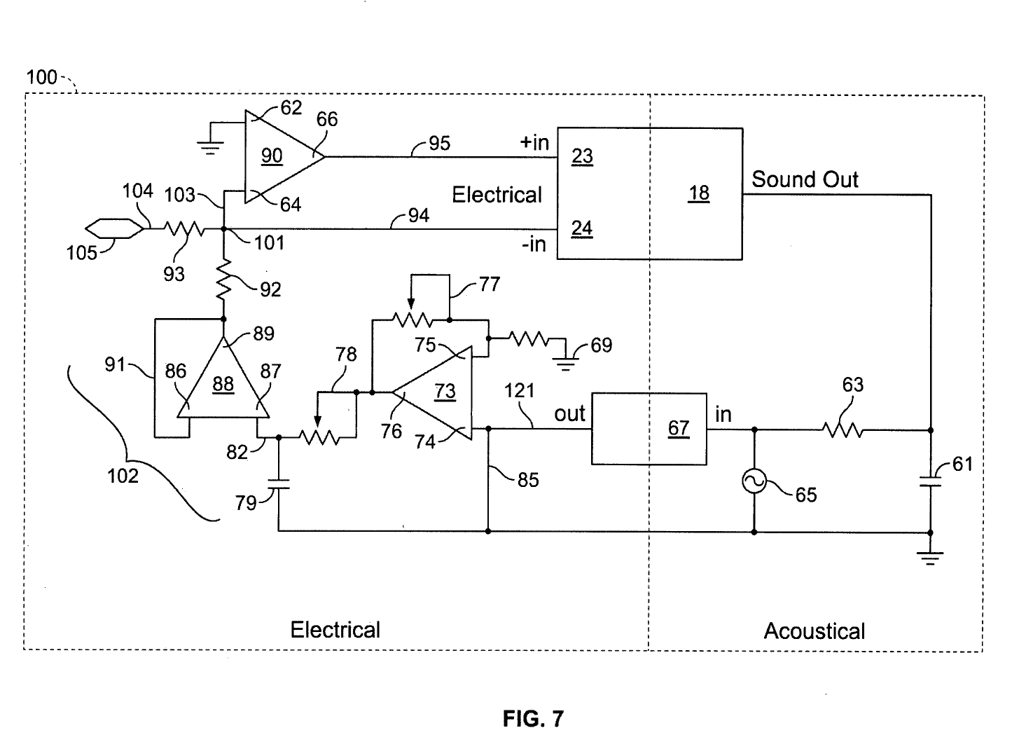

Another embodiment of the feed forward circuit 100 is depicted in FIG. 7. In this embodiment, a buffer stage 102 located in the circuit 100 between the sound to voltage converter stage 80, and the VCSC 90 such that an external audio input 105 can connect with the circuit 100. The external audio input 105 connects with the circuit 100 at a junction 101 located between the buffer stage 102 and the VCSC 90 via wire 104 to allow for normal operation of a typical earphone assembly 10. In one embodiment, wire 104 is within cable 16, and connects with the feed forward circuit 100 inside the junction unit 15 In this embodiment, the buffer stage 102 comprises a buffer amplifier 88 with a positive input terminal 87 a negative input terminal 86, and an output terminal 89. The positive input terminal 87 is connected to the acoustical to electrical voltage converter stage 80 via a wire 82. The negative input terminal 86 is connected to the output terminal via a loop 91. An adjustable resistor 92 is situated in series with the buffer amplifier 88 between the output terminal 89 and the junction 101. The external audio input 105 is connected to the junction 101 via a wire 104, and is in series with an adjustable resistor 93. The values of adjustable resistors 92 and 93 can be adjusted as needed to get the appropriate relative signal levels. A wire 103 connects the VCSC 90 to the circuit 100 by connecting the negative terminal 64 to the junction 101. In this embodiment the positive input terminal 62 is grounded such that the current signal delivered by the VCSC 90 is inverted 180 degrees in phase. In this embodiment amplifier 73 is wired as in the embodiment as shown in FIG. 5 so that only one 180 degrees phase shift occurs within the circuit. The output terminal 66 of the VCSC 90 is connected to the positive input terminal 23 of the receiver 18 via a wire 95. The junction 101 is also connected to the negative input terminal 24 of the receiver 18 via wire 94.

The feed forward technique constructs a cancellation signal that duplicates or mimics a signal measured outside the ear canal. In a preferred embodiment, both the microphone and receiver will have a flat (constant) transduction, in both amplitude and phase, including the frequency range where the feed forward technique is used. It is contemplated that the circuitry may be designed to compensate electronically for rising or falling slopes in the response.

In this and any embodiment, the exact value of any electrical element is unimportant, however, the values of certain elements as they relate to other elements may be. For instance, for optimal performance, the product of R_leak*C_{—}2cc should approximately equal the product of R_phase_shift*C_phase_shift, where R_leak is the acoustic resistance of the air leak path into the blocked ear canal (represented by resistor 63), C_{—}2cc is the volume of the ear canal (represented by capacitor 61), R_phase shift is the resistance of the phase shift potentiometer 78, and C_phase_shift is the capacitance of the phase shift capacitor 79. In a preferred embodiment, the resistance of the amplitude adjust potentiometer 77 is set such that with the phase shift capacitor 79 is absent and the ear canal is sealed with a passive noise reducing plug, the sound pressure in the ear canal equals the sound pressure outside the canal.

FIG. 8 depicts the Feed Forward circuit 100 as used in conjunction with the ER-4 receiver described above and depicted by FIG. 2. In this embodiment, the microphone 67 is attached to the earphone housing 20 with a microphone housing 120. Microphone wires 121 and 122 connect the microphone 67 to the cable 13 in strain relief member 28. Cable 13 electrically connects the microphone 67 to the feed forward circuit 100 located exterior to the earphone 11. In one embodiment, the remaining circuitry 100 of the feed forward circuit embodiments depicted by FIGS. 5-7 may be located inside the junction unit 15 of the earphone assembly 10, as depicted in FIG. 1. However, in embodiments involving the use of larger insert earphones 11, the feed forward circuit 100 may be located within the earphone 11 itself.

Theoretical Data

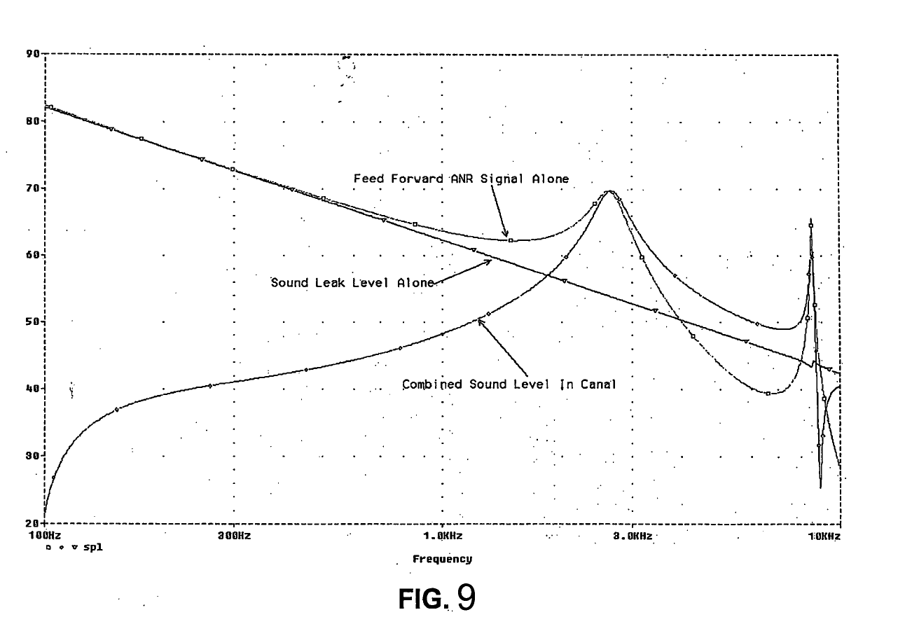

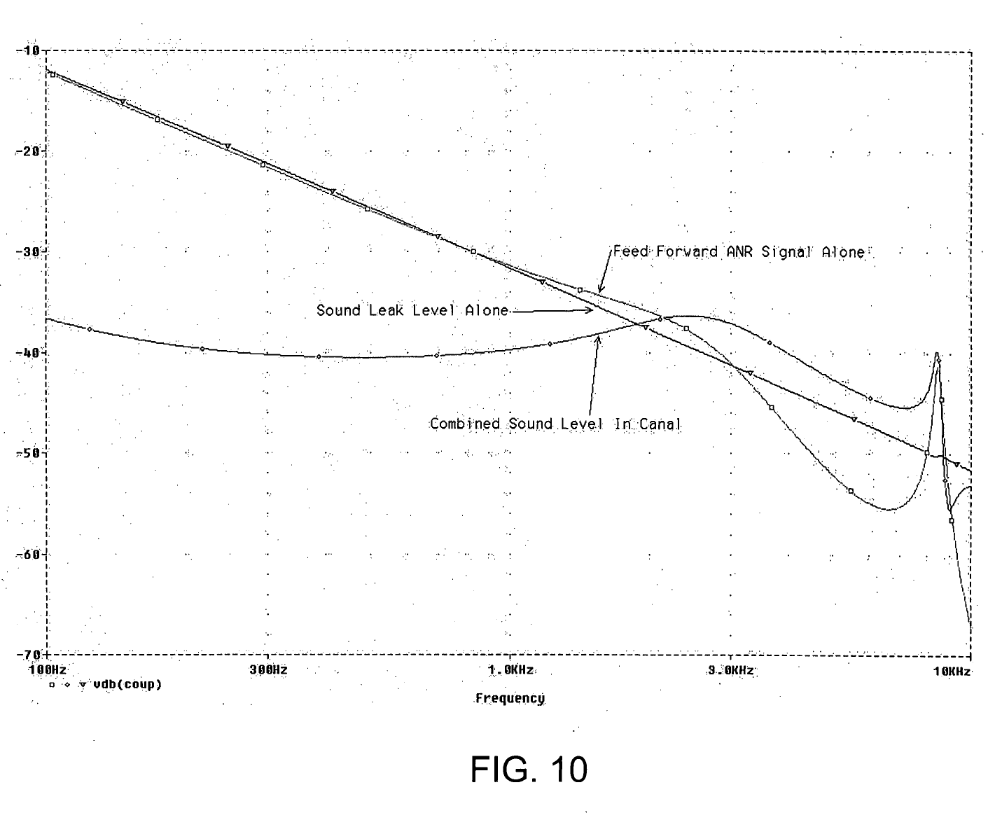

FIG. 9 depicts FIG. 9 is a graphical representation of a SPICE® calculation of the noise attenuation of an acoustical system comprising an ideal receiver (having a flat response), a coupler representing an ear canal sealed with an earplug having an acoustical leak, and an ideal (flat response) microphone. The simulation depicts the level of attenuation (represented by the Y axis) at a constant external sound pressure level (set at 94 db) using an embodiment of the feed forward technique where the amplifiers, the receiver, and the microphone have an absolutely flat response and no phase shift from input to output. The simulation of FIG. 9 shows that as the frequency of the external sound (represented by the X-axis) increases, the sound leak level into the ear canal decreases at a near linear rate. At low frequencies, particularly those near 100 Hz, the feed forward active noise reduction signal nearly matches the sound leak exactly, virtually eliminating the combined sound in the ear canal. FIG. 9 depicts that, in this embodiment, the combined sound level in the ear canal is significantly lower when the feed forward technique is used for external sound frequencies below 1.0 kHz. FIG. 10 demonstrates the results of a simulation using the acoustical system of FIG. 9 where damping is added to the receiver to reduce the resonance at higher frequencies. FIG. 10 shows that damping has improves the sound attenuation at higher frequencies.

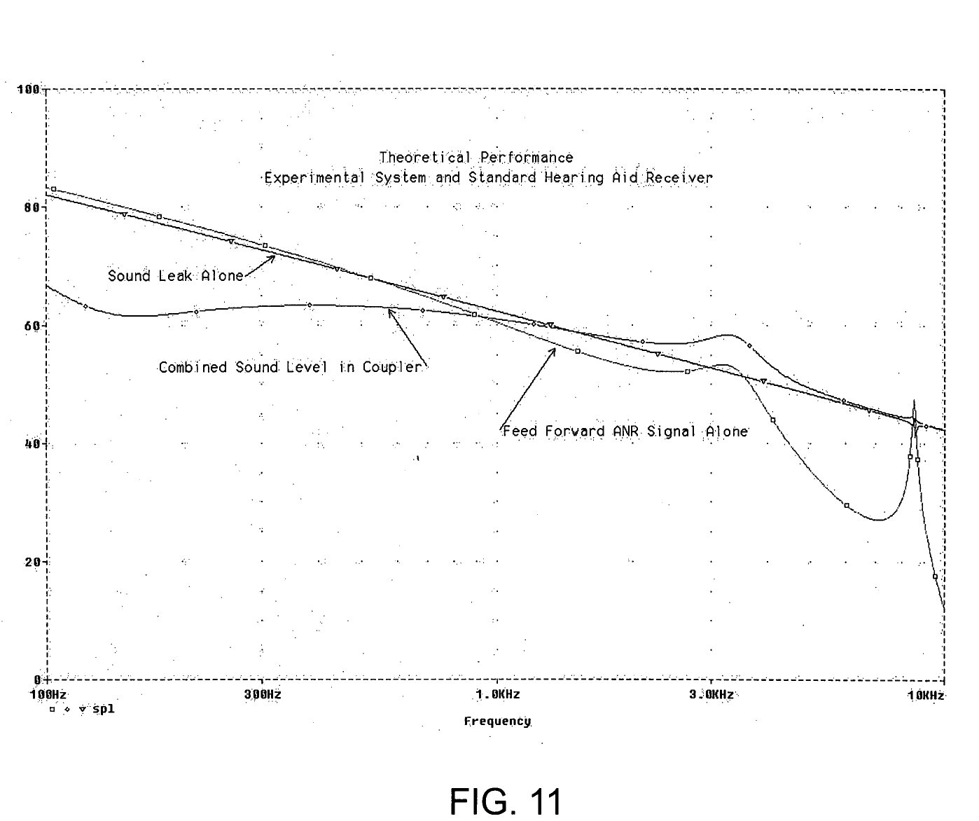

FIG. 11 depicts a graphical representation of a SPICE® calculation of the noise attenuation of an acoustical system where a standard hearing aid was used as the receiver instead. Again, it is shown that the feed forward circuitry performs effective noise attenuation at external sound frequencies below 1.0 kHz in spite of the lack of an ideal receiver.

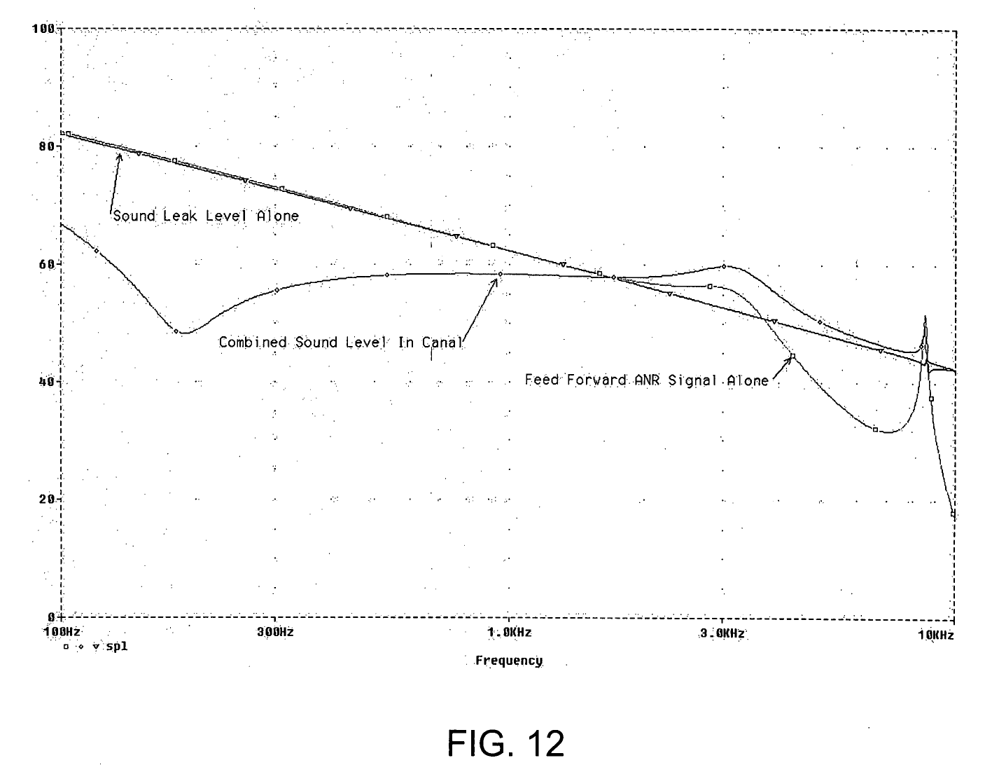

FIG. 12 depicts a graphical representation of the same a SPICE® calculation of an acoustical system where a commercial receiver such as the Etymotic ER-4 or ER-6 is used. The results demonstrate that the feed forward technique also improves attenuation in this embodiment at frequency values less than 1 kHz. circuitry is effective with a variety of interchangeable receiver types.

Experimental Data

Some experiments on feed forward active noise reduction circuitry were conducted using available equipment.

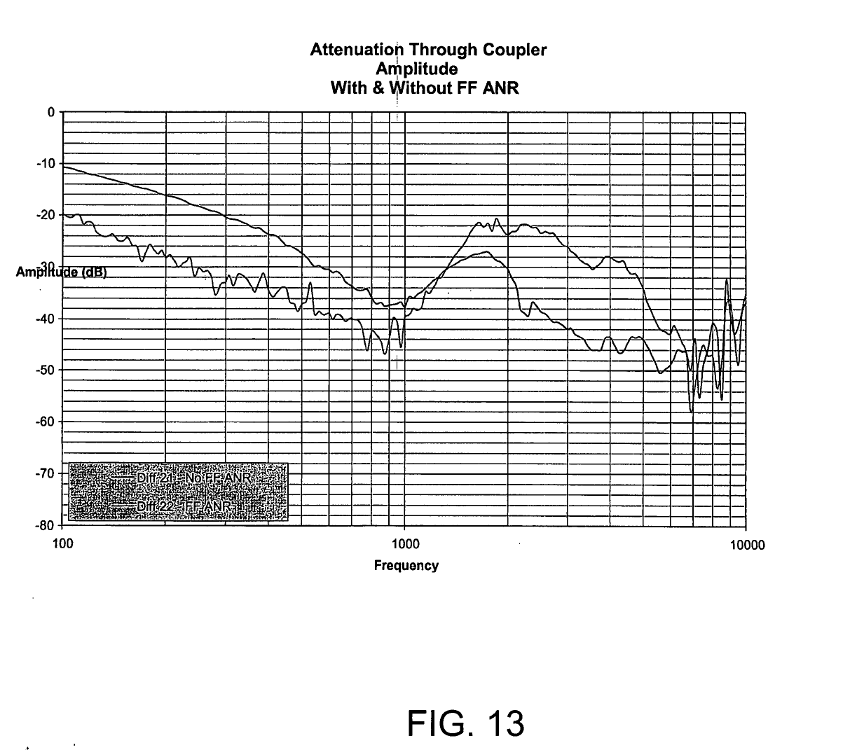

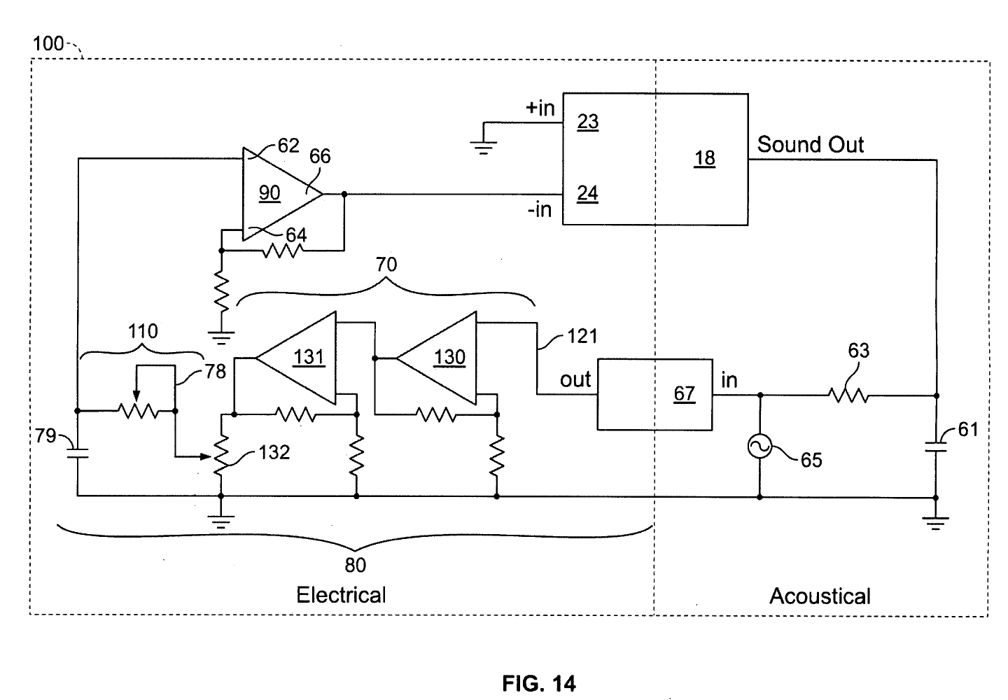

FIG. 13 shows the performance of tests performed using an Etymotic ER-6 (left) insert earphone receiver. A small cavity coupler was used instead of a real ear canal. A swept sound field of approximately 94 dB SPL was applied external to the sealed coupler and the sound field was recorded both inside and outside the coupler. The sound level within the coupler was accordingly measured, representing the sound within the ear canal. The coupler was blocked with a poorly fitted E-6 insert earphone to introduce a sound leak into the coupler. An external sound was applied at a constant noise level at frequencies ranging from 100 Hz to 10 kKz. An embodiment of the feed forward electric circuit was applied to the ER-6 receiver to attenuate the sound. A diagram of the embodiment applied to the circuit is depicted in FIG. 14. was used to attenuate the sound. Two low gain amplifiers 130, 131 were used to instead of a single high gain amplifier, and along with the an adjustable potentiometer 132, to constitute the signal amplitude adjuster loop 70. A phase shifter 110 and a VCSC 90 were used to convert the signal to a current source. The output terminal 66 of the VCSV was connected to the negative input terminal 24 of the receiver 18 to invert the signal. A voltage source (not shown) was used for the driver of the receiver 18. The values of the phase shifter 110 the amplitude potentiometer 132 were adjusted to maximize attenuation when the external sound frequency was at 100 Hz.

FIG. 13 depicts the results achieved from the experiment using the feed forward active noise reduction technique. At external noise frequencies (represented by the X-axis) below 1000 Hz, the sound within the ear canal (represented by the Y-axis) is lower when the feed forward circuitry is used (represented by line Diff 22—FF ANR) than when it was not used (represented by line Diff 21—No FF ANR). The attenuation at this stage is 12 dB at an external sound pressure of 100 Hz, but steadily decreases at 6 dB/octave as the frequency increases. The feed forward active noise reduction signal has the same slope at low frequencies, and reduces the sound within the coupler at all external sound frequencies below 1 kHz.

It should be noted that a properly applied ER-6 earphone by itself will approximately attenuate an external sound level by 40 dB or more, but for the experiment a sound leak was artificially introduced to represent a poorly fitted seal. The summation of the two signals of FIG. 13 depicts that, even with the sound leak installed, the feed forward active noise reduction used in conjunction with the passive noise reducing properties of the ER-6 receiver increases the amount of noise attenuated to a level of 40 dB or more at frequencies less than 1 kHz. This improvement demonstrates the feed forward technique can alleviate problems caused by earplugs that are not properly inserted.

The results of the experiments and simulations demonstrate that the feed forward technique has beneficial properties for all types of receivers, though the attenuation level may be greater when used in some receivers than it is in others. Accordingly, it is contemplated that a receiver and circuit may be designed for performance with one another to achieve optimal sound attenuation at all frequency levels.

Aspects of the invention provide an electronic solution to the mechanical problems involved with passive noise attenuation provided by existing earplugs and insert earphones. Important aspects of the invention relate to the recognition and discovery of problems with prior art arrangements of earplugs and insert earphones and their failure to effectively attenuate external sound from entering the ear canal.

In accordance with an embodiment of the invention, an insert earphone assembly is provided comprising a housing having an interior and an exterior. A resilient material is disposed over the exterior of the housing for sealing with an ear canal of a wearer. The sealing with an ear canal provides passive noise attenuation within the ear canal. A receiver is located within the housing of the earplug assembly for transducing electrical energy to sound energy, and delivering sound from an external device into the ear canal. In one embodiment, a cable including a plurality of electrical conductors extends from the insert earphone to an electrical audio signal source external to the housing.

In one embodiment, a feed forward electrical circuit is located within the housing of the insert earphone assembly. The electrical circuit is based upon an assumed correlation between the external sound outside the ear plug and the sound leakage into the ear canal. A microphone is located on the exterior of the housing and is connected to the electrical circuit. The microphone converts sound external to the ear to an electronic signal. A signal amplitude adjuster is electrically connected to the microphone in series to allow for adjustment of the amplification of the signal. In one embodiment, the signal amplitude adjuster comprises an operational amplifier connected in parallel with an adjustable potentiometer. An adjustable phase shifting potentiometer and a phase shift capacitor are also connected in series with the microphone and signal amplitude adjuster to allow the phase of the signal to be adjusted. A voltage to current source converter (“VCSC”) is connected in series with the microphone and signal amplitude adjuster and converts the voltage signal to a current. In one embodiment, the VCSC is an operational amplifier with a positive input terminal, a negative input terminal, and an output terminal. The electrical current signal from the VCSC is inverted and delivered to the receiver, where the current signal is converted into a sound pressure and fed forward into the ear canal.

In one embodiment, the negative input terminal of the VCSC is connected to the positive input terminal of the Receiver, and the output terminal of the VCSC is connected to the negative input terminal of the Receiver such that the signal delivered to the receiver is inverted. In another embodiment, a gain inverter stage is located in the feed forward circuit between the VCSC and the receiver, for adjusting the phase of the current signal 180 degrees.

In yet another embodiment the VCSC is achieved by inserting a large valued resistor between the voltage source and the receiver. The receiver also acts to attenuate the signal and can be used as an adjustment to signal level.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A hearing device for insertion into the ear, comprising:
a. a housing comprising a passive noise reduction mechanism for preventing noise from entering the ear canal; and
b. circuitry for actively canceling noise that enters the ear canal;
wherein the passive noise reduction mechanism and the circuitry combine to reduce noise in the ear canal beyond that provided by the passive noise reduction mechanism alone.

2. A feed forward electrical circuit comprising:
a. A sound to voltage converter comprising:
i. A microphone on the external of the housing for converting sound pressure external to the housing to a voltage,
ii. A signal amplitude adjuster comprising:
1. at least one amplifier:
2. At least one adjustable amplitude adjusting potentiometer connected to said at least one amplifier for adjusting the amplitude of the signal fed from the microphone;
iii. A phase shifter for shifting the phase of the microphone signal comprising;
i. A phase shift capacitor and
ii. A phase shifting potentiometer
b. A Means for inverting the phase of the signal 180 degrees
c. A means for delivering the signal to a sound producing source.

3. The feed forward electrical circuit of claim 2 further comprising a voltage to current source converter for converting the signal from the microphone to a current.
